(19) United States
(12) Patent Application Publication
(10) Pub. No.: US 2017/0162742 A1
(43) Pub. Date: Jun. 8, 2017

(54) PACKAGED SEMICONDUCTOR DEVICES AND RELATED METHODS

(71) Applicant: SEMICONDUCTOR COMPONENTS INDUSTRIES, LLC, Phoenix, AZ (US)

(72) Inventors: Atapol PRAJUCKAMOL, Klaeng (TH); How Kiat LIEW, Ipoh (MY); Bih Wen FON, Bukit Baru (MY)

(73) Assignee: SEMICONDUCTOR COMPONENTS INDUSTRIES, LLC, Phoenix, AZ (US)

(21) Appl. No.: 15/439,672

(22) Filed: Feb. 22, 2017

Related U.S. Application Data
(62) Division of application No. 14/516,289, filed on Oct. 16, 2014.

(51) Int. Cl. H01L 31/167; H01L 21/56; H01L 23/31; H01L 21/3105; H01L 23/495; H01L 31/02; H01L 23/00; H01L 21/78

(52) U.S. Cl. CPC H01L 31/167; H01L 24/83; H01L 21/561; H01L 21/565; H01L 21/78; H01L 21/31053; H01L 23/49503; H01L 23/49541; H01L 24/85; H01L 24/92; H01L 24/97; H01L 31/02005; H01L 23/3135; H01L 24/32; H01L 24/49; H01L 24/73; H01L 2224/32245; H01L 2224/48091; H01L 2224/48106; H01L 2224/48247; H01L 2224/73265; H01L 2224/92247; H01L 2924/12041; H01L 2924/12043; H01L 2924/1815

(57) ABSTRACT

A packaged semiconductor device includes a substrate, a die, at least one electrical connector, a first mold compound formed of translucent material, and a second mold compound. A first face of the die is electrically and mechanically coupled to the substrate. The at least one electrical connector electrically couples at least one electrical contact on a second face of the die with at least one conductive path of the substrate. The first mold compound formed of a translucent material at least partially encapsulates the die and the at least one electrical connector. The second mold compound at least partially encapsulates the first mold compound and forms a window through which the first mold compound is exposed. In implementations the second mold compound is opaque and the first mold compound is transparent. In implementations the substrate includes a lead frame having a die flag and a plurality of lead frame fingers.

### CROSS REFERENCE TO RELATED APPLICATIONS

This application is a divisional application of the earlier U.S. Utility Patent Application to Prajuckamol et al. entitled “Packaged Semiconductor Devices And Related Methods,” application Ser. No. 14/516,289, filed Oct. 16, 2014, now pending, the disclosure of which is hereby incorporated entirely herein by reference.

### BACKGROUND

1. Technical Field

Aspects of this document relate generally to semiconductor device packaging.

2. Background

Semiconductor devices are often encased within (or partly within) a package prior to use. Some packages contain a single die while others contain multiple die. The package offers protection to the die, such as from corrosion, impact and other damage, and often also includes electrical leads or other components which connect the electrical contacts of the die with a motherboard. The package may also include components configured to dissipate heat from the die into a motherboard or otherwise away from the package.

### SUMMARY

Implementations of packaged semiconductor devices may include: a substrate; a die mechanically coupled to the substrate at a first face of the die; at least one electrical connector electrically coupling at least one electrical contact on a second face of the die with at least one conductive path of the substrate; a first mold compound, formed of a translucent material, at least partially encapsulating the die and the at least one electrical connector; and a second mold compound partially encapsulating the first mold compound and forming a window through which the first mold compound is exposed.

Implementations of packaged semiconductor devices may include one, all, or any of the following:

The die may be electrically coupled to the substrate at the first face of the die.

The first mold compound may have substantially a shape of a spherical cap having an upper portion removed.

The second mold compound may be formed of an opaque material.

The first mold compound may be transparent.

At least a majority of the second face of the die may be exposed to light through the window.

The at least one electrical contact may include a plurality of electrical contacts, the substrate may be a lead frame, the at least one conductive path may include at least one die flag and a plurality of lead frame fingers of the lead frame, the die may be mechanically and electrically coupled to the die flag at the first face of the die, and the at least one electrical connector may electrically couple the plurality of electrical contacts on the second face of the die with the plurality of lead frame fingers.

Implementations of a method of forming a packaged semiconductor device may include: mechanically coupling a first face of a die with a substrate; electrically coupling at least one electrical contact on a second face of the die with at least one conductive path of the substrate using at least one electrical connector; at least partially encapsulating the die and the at least one electrical connector with a first mold compound formed of a translucent material; at least partially encapsulating the first mold compound in a second mold compound; and forming a window in the second mold compound to expose the first mold compound by removing a portion of the second mold compound and a portion of the first mold compound.

Implementations of a method of forming a packaged semiconductor device may include one, all, or any of the following:

Electrically coupling the first face of the die with the substrate.

Removing the portion of the second mold compound and the portion of the first mold compound may include one of grinding and polishing the second mold compound and the first mold compound.

Partially encapsulating the die and at least one electrical connector with the first mold compound may include forming substantially a shape of a spherical cap with the first mold compound.

The second mold compound may be formed of an opaque material.

The first mold compound may be transparent.

At least a majority of the second face of the die may be exposed to light through the window.

Implementations of a method of forming a packaged semiconductor device may include: mechanically and electrically coupling a first face of a die with a die flag of a lead frame; electrically coupling a plurality of electrical contacts on a second face of the die with a plurality of lead frame fingers of the lead frame using wire bonds; at least partially encapsulating the die, the wire bonds, the die flag, and a portion of each lead frame finger with a first mold compound formed of a translucent material; at least partially encapsulating the first mold compound and a portion of each lead frame finger in a second mold compound; and removing a portion of the second mold compound and a portion of the first mold compound through one of grinding and polishing to form a window in the second mold compound through which the second face of the die is exposed to light through the first mold compound.

Implementations of a method of forming a packaged semiconductor device may include one, all, or any of the following:

Partially encapsulating the die, the wire bonds, the die flag, and the portion of each lead frame finger with the first mold compound may include forming substantially a shape of a spherical cap with the first mold compound.

The second mold compound may be formed of an opaque material.

The first mold compound may be transparent.

All of the second face of the die may be exposed to light through the window.

The die may include one of a light source and a light sensor.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a side cross section view of a plurality of die on a substrate with electrical connectors coupling electrical contacts of the die with conductive paths of the substrate;

FIG. 2 is a side cross section view of the devices of FIG. 1 encapsulated in a uniform layer of a first mold compound;

FIG. 3 is a side cross section view of the devices of FIG. 1 partially encapsulated in a plurality of isolated sections of a first mold compound;

FIG. 4 is a side cross section view of the devices of FIG. 3 encapsulated in a uniform layer of a second mold compound;

FIG. 5 is a side cross section view of the devices of FIG. 4 with a portion of the second mold compound and a portion of the first mold compound removed;

FIG. 6 is a side cross section view of the devices of FIG. 5 singulated, forming a plurality of packaged semiconductor devices;

FIG. 7 is a side cross section view of the devices of FIG. 1 and a transfer mold for partially encapsulating the devices of FIG. 1 in a first mold compound; and

FIG. 8 is a side cross section view of an implementation of a packaged semiconductor device including a leadframe.

### DESCRIPTION

This disclosure, its aspects and implementations, are not limited to the specific components, assembly procedures or method elements disclosed herein. Many additional components, assembly procedures and/or method elements known in the art consistent with the intended packaged semiconductor devices and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such packaged semiconductor devices and related methods, and implementing components and methods, consistent with the intended operation and methods.

Referring now to FIGS. 1-6, in implementations a method of forming a plurality of semiconductor device packages may include mechanically and electrically coupling a die 2 or a plurality of die 2 to a substrate 4. Such methods may involve, by non-limiting example, using a pick-and-place tool, coupling the die 2 to the substrate 4 using a conductive adhesive and/or a solder, and the like. Electrical connectors 6 are placed to electrically couple at least one electrical contact on a second face 5 of the die 2 with one or more conductive paths of the substrate 4. The electrical connectors 6 could be clips, wire bonds 7, and the like. In implementations there are a plurality of electrical connectors 6 and they are used to electrically couple a plurality of electrical contacts on the second face 5 of the die 2 with a plurality of conductive paths of the substrate 4. In the implementations shown the first face 3 of the die 2 is on an opposite side of the die 2 from the second face 5 of the die 2. In other various implementations the first face 3 and second face 5 need not be on opposing sides of the die 2 but could be, by non-limiting example, on adjacent sides of the die 2.

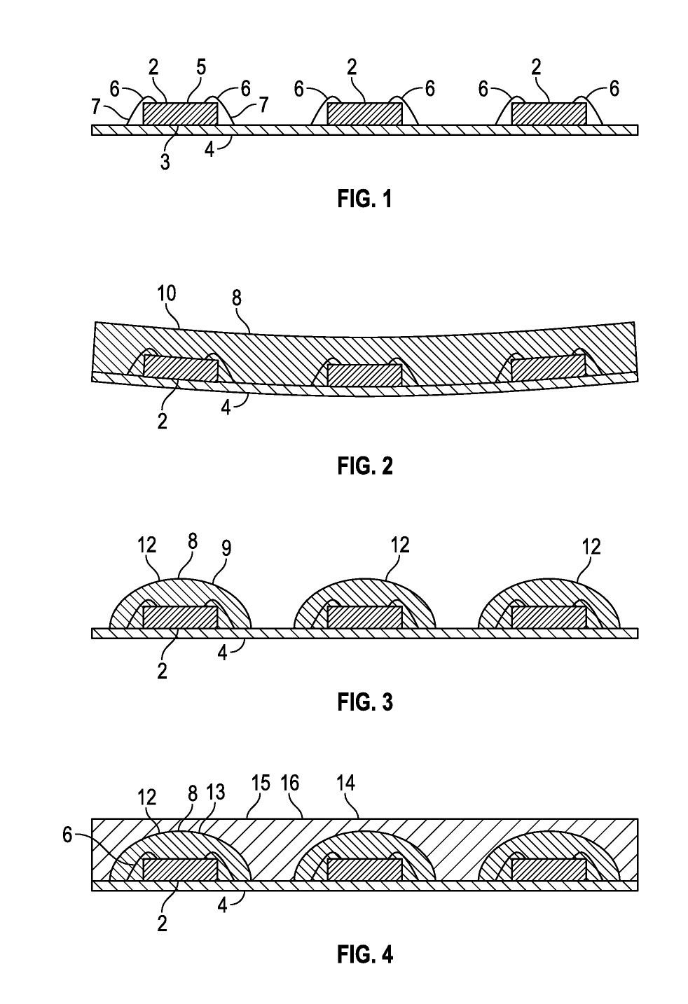

Referring now to FIG. 2, conventional methods of forming a semiconductor package encapsulate the various devices coupled to the substrate 4 in a uniform layer 10 of a first mold compound 8. The first mold compound 8 may be translucent, and in implementations may additionally be transparent. In implementations the first mold compound 8 may be or may include one or more mold compounds sold under the trade names KYOCERA TR2000 and/or KYOCERA TR1500 by Kyocera Chemical Corporation of Saitama, Japan, though the first mold compound 8 may be, or may include, any other translucent or transparent mold or other polymeric compound.

In conventional methods of packaging, the uniform layer 10 of the first mold compound 8, upon solidifying or cooling, undergoes volumetric shrinking which results in the upper surface of the first mold compound becoming less in surface area than the surface are of the substrate 4. This behavior results in a upwards curvature as depicted in FIG. 2, with tensile stresses in the first mold compound 8 and compressive stresses in the substrate 4 at the interface of the first mold compound 8 with the substrate 4. These stresses may result in deformation of the substrate 4, first mold compound 8, and other elements of FIG. 2, as illustrated in FIG. 2, including, e.g., forming an undesirable curvature or concavity in substrate 4.

The deformation shown in FIG. 2 is not drawn to scale and the actual deformation may be more or less than that shown in FIG. 2. In other implementations the stresses could result in a downwards curvature as the mold compound expands in volume and surface area rather than shrinking when particular first mold compounds are used. In some implementations there could be little to no curvature of the substrate but serious internal stresses present (or which would result during future operation). The present and future curvature and/or stresses may be caused, by non-limiting example, by coefficient of thermal expansion (CTE) mismatches between the first mold compound 8, substrate 4, and die 2 and/or due to cure shrinkage in the first mold compound 8 due to cross-linking during the curing process or CTE mismatches which occur later during operation of the die 2. While the elements shown in FIG. 2 are not singulated, because the stress is the result of the selection of the type of compound used as the first mold compound, after singulation some or all of the deformation and/or stresses will remain.

The first mold compound 8, as indicated above, is formed of a translucent material 13 or, in other words, as used herein, a material that allows light to pass therethrough. The first mold compound 8 may additionally be a transparent material or, in other words, as used herein, a material that transmits light without appreciable scattering so that objects may be seen clearly therethrough. The die 2 may include or be a light source (such as a light emitting diode (LED)) or, in other implementations, may be a light sensor. By non-limiting example, the die 2 in implementations may include a light emitting diode (LED), an ambient light sensor, a proximity sensor, a photodiode, a photovoltaic device, and other semiconductor devices that emit or sense electromagnetic radiation in a spectrum (frequency, wavelength, etc.) that the first mold compound allows to pass through to the die. Accordingly, the light that passes through the first mold compound 8 may be in the visible spectrum but in other implementations may be, or may include, light in other portions of the electromagnetic (EM) spectrum, including ultraviolet, infrared, and so forth.

Returning to FIG. 2, in implementations the deformation depicted in FIG. 2 may cause undesirable properties in packaged semiconductor devices. These undesirable properties may include, by non-limiting example, one or more or all of the following: undesirable electric properties of the die 2 due to compressive or tensile stresses or deformation of the die 2; delamination of the substrate 4 from the first mold compound 8, delamination of the substrate 4 from the die 2, and/or delamination of the die 2 from the first mold compound 8; reduced translucency or transparency of the first mold compound 8; other deviations in the optical characteristics of the first mold compound 8; downstream processing difficulties caused by the warpage of the substrate 4. Because the first mold compound 8 is formed of a translucent material 13 and, in some implementations, a transparent material, the practitioner may have relatively few materials to select from for use as a first mold compound 8, and having to deal with the prospect of warpage may complicate the manufacturability of such a packaging solution significantly.

Referring now to FIGS. 1 and 3, in implementations of a method of forming a packaged semiconductor device a plurality of die 2 are coupled to a substrate 4 at first faces 3 of the plurality of die 2 and a plurality of electrical connectors 6 are used to couple electrical contacts on a second face 5 of the die 2 with conductive paths of the substrate 4. Instead of then placing a mold compound in a uniform layer 10, a plurality of isolated mold sections 12 are placed (formed) such that they at least partially encapsulate (and, in the implementations shown in the drawings, fully encapsulate) each of the plurality of die 2 and the electrical connectors 6 associated with each die 2. In various implementations each isolated mold section 12 encapsulates only one die 2 and its associated electrical connectors 6. The isolated mold sections 12 are formed of the first mold compound 8 and include a translucent material 13 (or a transparent material, depending on the implementation). In particular implementations, different first mold compound materials may be placed over different die on the same substrate to create various design/optical effects. For example, if the die are LEDs which emit white light, one translucent first mold compound that has a red coloring may be placed over some die and another translucent first mold compound that has a blue coloring may be placed over other die. The resulting optical effect is to create die that emit red light and other die that appear to emit blue light because of the coloring of the respective first mold compounds. Many possible variations are possible to those of ordinary skill. The translucent material 13 may be the same (or a similar) material from which the uniform layer 10 is formed in conventional methods of forming a packaged semiconductor device. Each isolated mold section 12 at this stage of processing may have the shape 9 of (or substantially of, as shown in FIG. 3) a spherical cap or dome. The viscosity of the first mold compound 8 may be tailored to properly form the desired dome or spherical cap shape 9 or other shape that volumetrically encapsulates the die 2.

The isolated mold sections 12 may be created using various methods, including, by non-limiting example: dispensing the first mold compound 8 in liquid form using a moving dispensing head that drops/dispenses a predetermined amount of the first mold compound 8 onto each respective die and then processing the coated die forming each isolated mold section 12 in various ways to cure and solidify the first mold compound through heating, ultraviolet (UV) light exposure, baking, drying, and so forth. In particular implementations, the KYOCERA TR2000 compound may be used with this method, though any other translucent or transparent mold compound may also be used. Other methods of forming the isolated mold sections 12 may include using transfer molding to dispense the first mold compound 8 and then allowing it to cure and solidify using any of the methods disclosed herein. In particular implementations, the KYOCERA TR1500 compound may be used with this method, though any other translucent or transparent mold compound may also be used.

Referring now to FIGS. 3-5, the isolated mold sections 12 in the implementations shown do not contact one another, and accordingly some portions of a top surface of the substrate 4 (facing the first faces 3 of the die 2) are left exposed. The overall surface area of the top face of the substrate 4 that is contacted by the first mold compound 8 is therefore reduced compared with the conventional device of FIG. 2. This may essentially eliminate any deformation of the substrate 4 common with conventional methods as shown in FIG. 2.

After the isolated mold sections 12 have been cured and/or solidified, a uniform layer 16 of a second mold compound 14 is used to fully encapsulate the isolated mold sections 12 of the first mold compound 8 and the remaining portions of the top face of the substrate 4 that were not covered by the first mold compound 8. The second mold compound 14 may be formed of an opaque material 15. As used herein, an opaque material is one that does not substantially transmit visible radiation or otherwise does not transmit other electromagnetic radiation. Forming the second mold compound 14 from an opaque material 15 may allow the practitioner to have more materials to select from and therefore select a material that has properties lending themselves to preventing or countering the type of deformation present in the conventional method shown in FIG. 2. By non-limiting example, the second mold compound 14 may be, or may include, a material that does not undergo as much volumetric shrinking or expanding during solidifying or cooling as the first mold compound 8. By non-limiting example, in instances where the first mold compound 8 and second mold compound 14 are heated or melted during the dispensing or molding process, the second mold compound 14 could have a lower coefficient of thermal expansion than the first mold compound 8 and, accordingly, could undergo less shrinking when cooling down and/or solidifying. In implementations the second mold compound 14 may include a mold compound sold under the trade name EME-G760 by Sumitomo Bakelite Co., Ltd. of Tokyo, Japan, though in other implementations other mold compounds could be used.

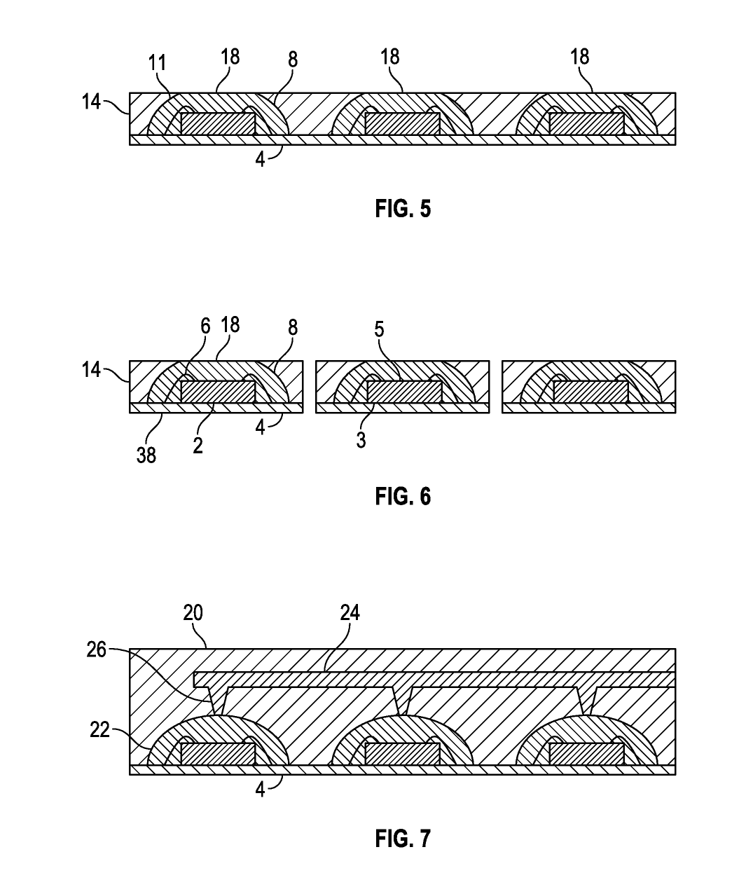

Referring now to FIG. 5, after the second mold compound 14 has solidified and/or cured, a portion of the second mold compound 14 and a portion of the first mold compound 8 are removed to form a window 18 in the second mold compound 14. The window 18 allows the die 2 to be exposed to light through the first mold compound 8 and/or allows light from the die 2 to travel through the first mold compound 8 to outside the packaged semiconductor device. One or more grinding and/or polishing steps may be utilized to remove the portion of the first mold compound 8 and second mold compound 14. A first grinding or polishing step using a coarser grit, for example, may first be used in order to remove material more quickly, while a second fine grinding, polishing, or lapping step using a finer grit may be used in order to provide a smooth finish. A finer grit process may also allow a surface of the first mold compound 8 at the window 18 to be smooth and have a substantially smooth, planar surface in order to allow light to pass through the surface without too much scattering. In some implementations the initial material removal step is a dry process, such as mechanical grinding, while later material removal steps are either dry processes such as mechanical grinding with finer grinding elements or a wet process such as lapping.

In FIG. 4 it is shown that the second mold compound 14 fully encapsulates the isolated mold sections 12, though it is also described herein that in alternative implementations the second mold compound 14 need not fully encapsulate the isolated mold sections 12. By non-limiting example, in some processes the second mold compound 14 could be flowed only until it is slightly above its final grinded and polished position shown in FIG. 5, so that a portion of each isolated mold section 12 extends above through a window in the second mold compound 14, and then the polishing and/or grinding steps could result in a substantially flat upper surface of the packaged semiconductor devices. Such a method could result in reduced cost due to less of the second mold compound 14 being used.

After the grinding and/or polishing steps a plurality of packaged semiconductor devices have been formed. Each isolated mold section 12 has a shape 9 of a spherical cap or dome with an upper portion removed (in the implementations shown each isolated mold section 12 has a shape 11 of a spherical cap with a smaller spherical cap removed from its top). This shape allows light to pass through the window 18 and through the first mold compound 8 while not having sharp edges at the interface between the first mold compound 8 and second mold compound 14, which may reduce the potential for crack initiation, delamination, and the like, at this interface.

Referring to FIG. 6, after the grinding and/or polishing steps the assembly may be singulated to form a plurality of packaged semiconductor devices 38. In implementations some of the steps mentioned herein may be done in different orders. For example the grinding and/or polishing steps could be done after the singulation step in some implementations depending upon the assembly process for the devices.

FIG. 7 shows a transfer mold 20 that may be used to dispense the first mold compound 8 to form isolated mold sections 12. The transfer mold 20 includes a plurality of cavities 22, each cavity 22 corresponding with a die 2 and its electrical connectors 6 and having the shape 9 of a spherical cap. The cavities 22 are each accessed through a gate 26 that connects to a runner 24. The first mold compound 8 may be dispensed to each respective location to form the isolated mold sections 12 and then the transfer mold 20 may be removed so that the second mold compound 14 may be applied. Such a transfer mold may be used in situations where the first mold compound 8 is not discretely dispensed over each die.

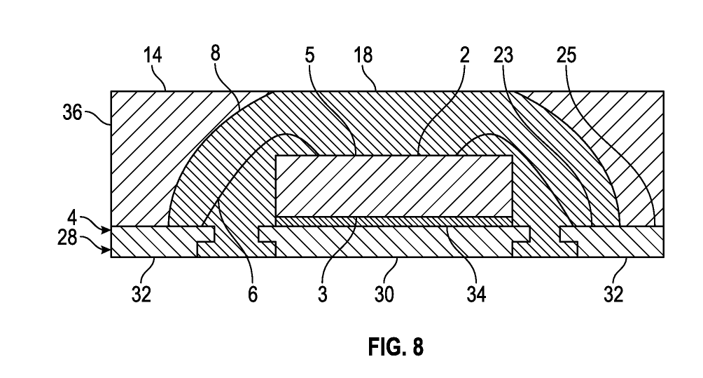

FIG. 8 shows a packaged semiconductor device 36 formed using methods described herein wherein the packaged semiconductor device 36 is a quad flat no-leads (QFN) package and wherein the substrate 4 is a lead frame 28 having a die flag 30 and a plurality of lead frame fingers 32. A first face 3 of the die 2 is coupled to the die flag 30, by non-limiting example, using a conductive adhesive 34. When the first mold compound 8 is applied it encapsulates the die 2, die flag 30, conductive adhesive 34, electrical connectors 6, and a first portion 23 of each lead frame finger 32, but not a second portion 25 of each lead frame finger 32. When the second mold compound 14 is applied it encapsulates the first mold compound 8 and a second portion 25 of each lead frame finger 32. This illustrates how the methods shown herein may be employed for both substrate and leadframe assembly processes.

Forming the first mold compound 8 into spherical cap shapes 9 (and/or isolated mold sections 12 in general) may reduce cost due to less of the translucent (or transparent) first mold compound 8 being used in situations where the first mold compound 8 is more expensive than the second mold compound 14 used later in the process. Use of the spherical cap or dome shape 9 may result in increased crack resistance as opposed to other shapes for the isolated mold section 12 due to a smooth surface without edges at the interface between the first mold compound 8 and second mold compound 14.

In places where the description above refers to particular implementations of packaged semiconductor devices and related methods and implementing components, sub-components, methods and sub-methods, it should be readily apparent that a number of modifications may be made without departing from the spirit thereof and that these implementations, implementing components, sub-components, methods and sub-methods may be applied to other packaged semiconductor devices and related methods.

What is claimed is:

1. A method of forming a packaged semiconductor device, comprising:
mechanically coupling a first face of a die with a substrate;
electrically coupling at least one electrical contact on a second face of the die with at least one conductive path of the substrate using at least one electrical connector;
at least partially encapsulating the die and the at least one electrical connector with a first mold compound comprised of a translucent material;
at least partially encapsulating the first mold compound in a second mold compound;
forming a window in the second mold compound to expose the first mold compound by removing a portion of the second mold compound and a portion of the first mold compound; and
singulating the plurality of die after removal of the portion of the first mold compound and the portion of the second mold compound into a plurality of semiconductor packages.

2. The method of claim 1, further comprising electrically coupling the first face of the die with the substrate.

3. The method of claim 1, wherein forming a window in the second mold compound further comprises one of grinding and polishing the second mold compound and the first mold compound.

4. The method of claim 1, wherein partially encapsulating the die and at least one electrical connector with the first mold compound comprises forming substantially a shape of a spherical cap with the first mold compound.

5. The method of claim 1, wherein the second mold compound is comprised of an opaque material.

6. The method of claim 1, wherein the first mold compound is transparent.

7. The method of claim 1, wherein at least a majority of the second face of the die is exposed to light through the window.

8. A method of forming a packaged semiconductor device, comprising:
mechanically and electrically coupling a first face of a die with a die flag of a lead frame;
electrically coupling a plurality of electrical contacts on a second face of the die with a plurality of lead frame fingers of the lead frame using wire bonds;
at least partially encapsulating the die, the wire bonds, the die flag, and a portion of each lead frame finger with a first mold compound comprised of a translucent material;
at least partially encapsulating the first mold compound and a portion of each lead frame finger in a second mold compound;
removing a portion of the second mold compound and a portion of the first mold compound through one of grinding, polishing, and any combination thereof to form a window in the second mold compound through which the second face of the die is exposed to light through the first mold compound; and
singulating the plurality of die after removal of the portion of the first mold compound and the portion of the second mold compound into a plurality of semiconductor packages.

9. The method of claim 8, wherein partially encapsulating the die, the wire bonds, the die flag, and the portion of each lead frame finger with the first mold compound comprises forming substantially a shape of a spherical cap with the first mold compound.

10. The method of claim 8, wherein the second mold compound is comprised of an opaque material.

11. The method of claim 8, wherein the first mold compound is transparent.

12. The method of claim 8, wherein all of the second face of the die is exposed to light through the window.

13. The method of claim 8, wherein the die comprises one of a light source and a light sensor.

14. A method of forming a plurality of packaged semiconductor devices, comprising:
providing a lead frame comprising a plurality of die flags and a plurality of lead frame fingers;
mechanically coupling a plurality of die to each of a plurality of die flags at a first face of each of the plurality of die;
electrically coupling at least one electrical connector to at least one electrical contact on a second face of the plurality of die with at least one lead frame finger of the plurality of lead frame fingers;
at least partially encapsulating the plurality of die and the at least one electrical connector with a first mold compound, the first mold compound comprised of a translucent material;
at least partially encapsulating the first mold compound and forming a window through which the first mold compound is exposed;
removing a portion of the first mold compound and a portion of the second mold compound during processing of the lead frame by one of grinding, polishing, and any combination thereof; and
singulating the plurality of semiconductor devices into a plurality of semiconductor packages after removal of the portion of the first mold compound and the portion of the second mold compound.

15. The method of claim 14, wherein each of the plurality of die is electrically coupled to each of the plurality of die flags at the first face of each of the plurality of die.

16. The method of claim 14, wherein the first mold compound is located over each of the plurality of die comprises substantially a shaped of a spherical cap having an upper portion removed.

17. The method of claim 14, wherein the second mold compound is comprised of an opaque material.

18. The method of claim 14, wherein the first mold compound is transparent.

19. The method of claim 14, wherein at least a majority of the second face of each of the plurality of die is exposed to light through the window.

20. The method of claim 14, wherein the die comprises one of a light source and a light sensor.
